(19) United States
(12) Patent Application Publication
(10) Pub. No.: US 2016/0374193 A1
(43) Pub. Date: Dec. 22, 2016

(54) DISPLAY DEVICE

(71) Applicant: Samsung Display Co., Ltd., Yongin-si (KR)

(72) Inventor: Jun Namkung, Asan-si (KR)

(21) Appl. No.: 14/992,846

(22) Filed: Jan. 11, 2016

(30) Foreign Application Priority Data
Jun. 17, 2015 (KR) 10-2015-0085975

(51) Int. Cl. H05K 1/02; H05K 1/11; H05K 5/00

(52) U.S. Cl. CPC H05K 1/0271; H05K 5/0017; H05K 1/028; H05K 1/111

(57) ABSTRACT

A display device is disclosed. In one aspect, the display device includes a first substrate including a display area configured to display an image and a first pad region neighboring the display area. The display device also includes a second substrate including a second pad region. The second pad region includes a driving circuit. The display device also includes a connector connecting the first pad region to the second pad region, the connector including a wiring that electrically connects the display area to the driving circuit.

### INCORPORATION BY REFERENCE TO ANY PRIORITY APPLICATIONS

This application claims priority to and the benefit of Korean Patent Application No. 10-2015-0085975 filed in the Korean Intellectual Property Office on Jun. 17, 2015, the entire contents of which are incorporated herein by reference.

### BACKGROUND

Field

The described technology generally relates to a display device.

Description of the Related Technology

Light and impact-resistant flexible display devices are being developed. These displays can be folded or rolled to maximize portability and can be used in various applications.

Generally, a flexible display includes a display area for displaying an image and a peripheral area surrounding the display area. In the peripheral area, various voltage pads for receiving voltages from sources external to the display are formed. However, such a peripheral area does not display an image, and thus, is dead space, and the display area decreases as the dead space increases, thereby undermining the goal to meet recent demand for display devices with greater size and resolution.

In addition, when flexible display devices are bent or folded, a bending stress is applied to a display panel, and thus, cracks and the like are generated. Excess stress and cracks damage thin film transistors and/or light-emitting elements.

The above information disclosed in this Background section is only to enhance the understanding of the background of the described technology and therefore it may contain information that does not constitute the prior art that is already known in this country to a person of ordinary skill in the art.

### SUMMARY OF CERTAIN INVENTIVE ASPECTS

One inventive aspect relates to a display device that has reduced dead space and can prevent cracks and the like from being generated.

Another aspect is a display device including: a first substrate including a display area for displaying an image and a first pad region neighboring the display area; a second substrate including a second pad region formed with a driving unit; and a connecting portion connecting the first pad region and the second pad region. The connecting portion includes a wiring part that electrically couples the display area to the driving unit.

The connecting portion can include: a first region that includes a first wiring part; a second region that neighbors the first region and includes a second wiring part; and a third region that neighbors the second region and includes a third wiring part.

A width of the first wiring part can be smaller than a width of the second wiring part, and a width of the second wiring part can be smaller than a width of the third wiring part.

A length of the first wiring part can be greater than a length of the second wiring part, and the length of the second wiring part can be greater than a length of the third wiring part.

The second substrate can be a printed circuit board (PCB).

The second pad region can further include a PCB connected to a second side that is opposite to a first side to which the connecting portion is connected.

A material forming the connecting portion can have an extension rate in the range of about 2% to about 100%.

The connecting portion can include one or more selected from a group of copper (Cu), aluminum (Al), at least one alloy of these metals, silver (Ag), graphene, and a graphene oxide.

At least one of the first and second pad regions can be connected to the connecting portion via a thermosetting adhesive.

The connecting portion can be bent toward an opposite side of the display area of the first substrate, and the second substrate can be formed to overlap the first substrate at the opposite side of the display area.

A curvature radius of the connecting portion can be 1.5R or less

Another aspect is a display device, comprising: a first substrate including a display area configured to display an image and a first pad region neighboring the display area; a second substrate including a second pad region, wherein the second pad region includes a driving circuit; and a connector connecting the first pad region to the second pad region, wherein the connector includes a wiring that electrically connects the display area to the driving circuit.

In the above display device, the connector includes: a first region including a first wiring; a second region adjacent to the first region and including a second wiring; and a third region adjacent to the second region and including a third wiring.

In the above display device, the width of the first wiring is less than the width of the second wiring, wherein the width of the second wiring is less than the width of the third wiring.

In the above display device, the length of the first wiring is greater than the length of the second wiring, wherein the length of the second wiring is greater than the length of the third wiring.

In the above display device, each of the first to third wirings has a square wave shape.

In the above display device, each of the first to third wirings has a plurality of bent portions, wherein a first distance between of adjacent bent portions of the third wiring is greater than a second distance between adjacent bent portions of the second wiring, and wherein the second distance is greater than a third distance between adjacent bent portions of the first wiring.

In the above display device, the second substrate includes a printed circuit board (PCB).

In the above display device, the second pad region has a first end connected to the connector and a second end opposing the first end, wherein the second pad region further includes a PCB electrically connected to the second end.

In the above display device, the connector is formed of a material having an extension rate in the range of about 2% to about 100%.

In the above display device, the connector is formed of one or more of copper (Cu), aluminum (Al), at least one alloy of those metals, silver (Ag), graphene, and a graphene oxide.

In the above display device, at least one of the first and second pad regions is connected to the connector via a thermosetting adhesive.

In the above display device, the connector is bent toward an opposite side of the display area of the first substrate, wherein the second substrate overlaps the first substrate in the depth dimension of the display device.

In the above display device, a curvature radius of the connector is about 1.5R or less.

The above display device further comprises a protection film formed on the first substrate and configured to protect the first substrate.

In the above display device, the second substrate includes a flexible PCB.

Another aspect is a display device, comprising: a first substrate including a display area and a first pad region adjacent to the display area; a second substrate including a second pad region, wherein the second pad region includes a driving circuit; and a connector connecting the first pad region to the second pad region, wherein the width of the second pad region is greater than the width of the first pad region.

In the above display device, the connector includes a wiring configured to electrically connect the display area to the driving circuit.

The above display device further comprises a display element layer formed on the first substrate and configured to display an image, wherein the connector has first and second ends opposing each other, wherein the first end of the connector is formed on the display element layer, and wherein the second end of the connector is formed on the second substrate.

The above display device further comprises a flexible PCB formed on the second substrate, wherein the flexible PCB and the second end of the connector are formed on the same side of the second substrate.

In the above display device, the wiring includes a plurality of wirings including a leftmost wiring and a rightmost wiring, wherein the widths of the wirings decrease as a function of distance from the leftmost and rightmost wirings.

According to at least one of the disclosed embodiments, a display device can have a dramatically decreased dead space size as well as prevent cracks and the like from being generated.

### BRIEF DESCRIPTION OF THE DRAWINGS

FIG. 1 is a top plan view of a display device according to an exemplary embodiment.

FIG. 2 is a cross-sectional view of the display device of FIG. 1 folded back along a bending line.

FIG. 3 is a layout view of one pixel of the display device according to the exemplary embodiment.

FIG. 4 is a cross-sectional view of the display device of FIG. 3 taken along the line IV-IV.

FIG. 5 is a top plan view of a display device according to another exemplary embodiment.

FIG. 6 is a cross-sectional view of the display device of FIG. 5 folded back along a bending line.

FIGS. 7 and 8 are enlarged views of various examples of a region A of FIG. 1.

FIG. 9 is a cross-sectional view of a display device according to a further exemplary embodiment folded back along a bending line.

### DETAILED DESCRIPTION OF CERTAIN INVENTIVE EMBODIMENTS

The present disclosure will be described more fully hereinafter with reference to the accompanying drawings, in which exemplary embodiments of the disclosure are shown. As those skilled in the art would realize, the described embodiments can be modified in various different ways, all without departing from the spirit or scope of the present disclosure.

Throughout the specification, it will be understood that when an element such as a layer, film, region, or substrate is referred to as being “on” another element, it can be directly on the other element or intervening elements can also be present. Further, the word “on” means positioned on or below the object portion, and does not necessarily mean positioned on the upper side of the object portion based on a gravitational direction.

Throughout the specification, unless explicitly described to the contrary, the word “comprise” will be understood to imply the inclusion of stated elements but not the exclusion of any other elements. In the drawings, the sizes and thicknesses of respective elements are arbitrarily illustrated for ease of description, and the present disclosure is not necessarily limited to such size and thickness as illustrated. Like reference numerals designate like elements throughout the specification. In this disclosure, the term “substantially” includes the meanings of completely, almost completely or to any significant degree under some applications and in accordance with those skilled in the art. The term “connected” can include an electrical connection.

With reference to the drawings, the present disclosure will now be described in detail.

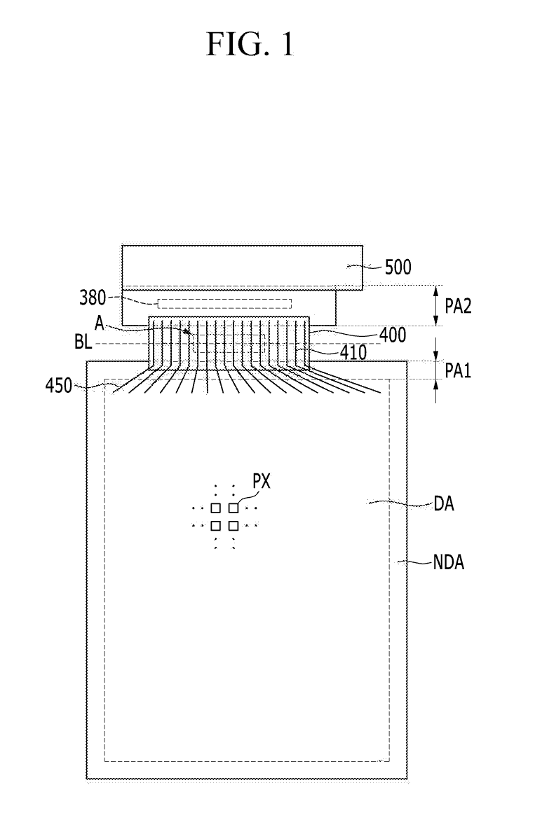

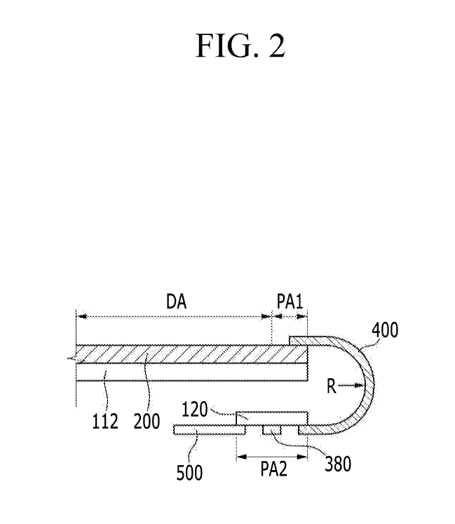

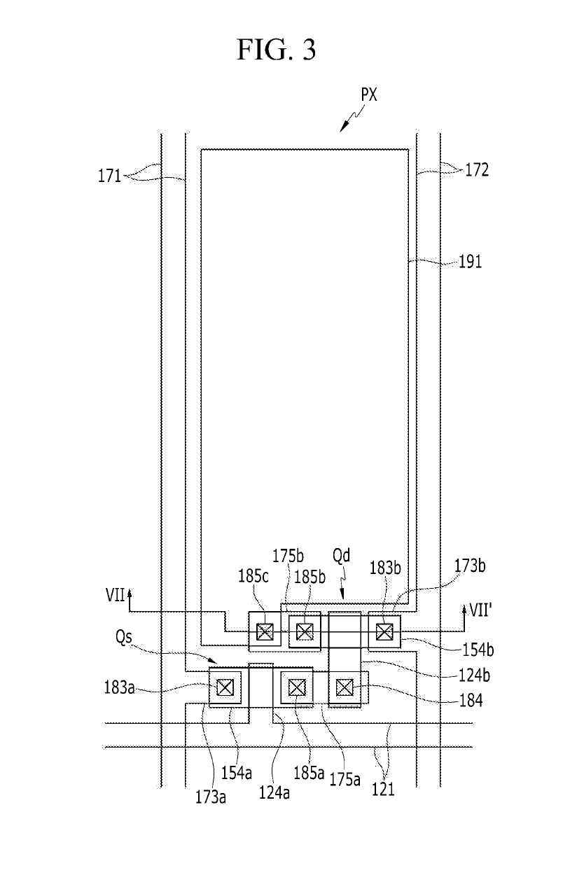

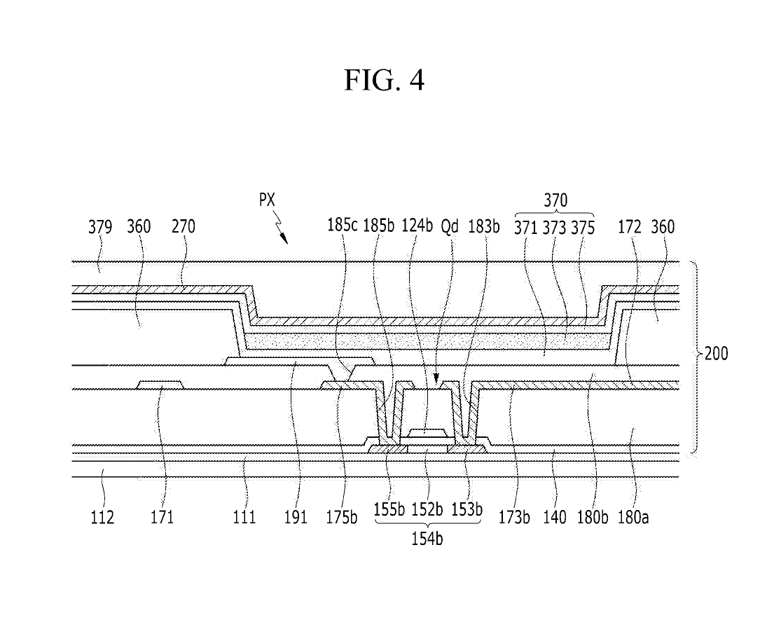

FIG. 1 is a top plan view of a display device according to an exemplary embodiment. FIG. 2 is a cross-sectional view of the display device of FIG. 1 folded back along a bending line. FIG. 3 is a layout view of one pixel of the display device according to the exemplary embodiment. FIG. 4 is a cross-sectional view of the display device of FIG. 3 taken along the line IV-IV.

First, referring to FIGS. 1 and 2, the display device according to the current exemplary embodiment includes: a display area DA; a first substrate 112 including a first pad region PA1 neighboring the display area DA; a second substrate 120 including a second pad region PA2 formed with a driving unit (or driving circuit) 380; and a connecting portion (or connector) 400.

In this case, the first substrate 112 can include the display area DA for displaying an image and a peripheral area NDA surrounding the display area DA. In this case, the first pad region PA1 to which the connecting portion 400 is connected is included in the peripheral area NDA, and can be formed at one side thereof to neighbor the display area DA.

The display area includes a plurality of pixels PX and thus serves as an area for displaying an image. The first pad region PA1 is electrically coupled to a driving chip of the second pad region PA2 and thus serves as a region to which the connecting portion 400 for transmitting electrical signals to the display area DA is attached. That is, in the present specification, the region where driving unit 380 is formed is referred to as the second pad region PA2.

In the display device according to the current exemplary embodiment, the first substrate 112 is a flexible substrate that is flexible enough to be easily bent, and includes, for example, plastic and the like. For example, the first substrate 112 is formed of polyethylene terephthalate (PET), polyethylene naphthalate (PEN), polycarbonate (PC), polyarylate (PAR), polyetherimide (PEL), polyether sulfone (PES), or polyimide (PI), but it is limited thereto.

A barrier layer (not shown) can be formed on the first substrate 112. The barrier layer can prevent external impurities from passing through the first substrate 112 and then penetrating a display element layer thereon, and a surface of the barrier layer can be flatly formed. For example, the barrier layer includes at least one of an inorganic layer and an organic layer, and includes, for example, a silicon nitride (SiNx), a silicon oxide (SiOx), a silicon oxynitride (SiOxNy), etc., but it is not limited thereto. If necessary, the barrier layer can be omitted.

A display element layer 200 including a plurality of thin films can be formed on the barrier layer. The display element layer 200 includes a plurality of signal lines that are formed in the display area DA, and a plurality of pixels PX that are connected the signal lines and arranged in an approximate matrix form. In this case, the signal lines can include a plurality of scanning signal lines for transmitting a scanning signal and a plurality of data lines for transmitting a data signal.

With reference now to FIGS. 3 and 4, one illustrative structure of the display element layer 200 will be described in detail.

First, a plurality of first semiconductors 154a and a plurality of second semiconductors 154b are formed on a barrier layer 111. The first semiconductor 154a can include a channel region (not shown), and a source region (not shown) and a drain region (not shown) that are formed by doping at opposite sides of the channel region. The second semiconductor 154b can include a channel region 152b , and source and drain regions 153b and 155b that are formed by doping to be formed at opposite lateral sides of the channel region 152b . The first and second semiconductors 154a and 154b can include amorphous silicon, polysilicon, or an oxide semiconductor.

Next, a gate insulating layer 140 that can be formed of a silicon nitride (SiNx) or a silicon oxide (SiOx) is formed on the first and second semiconductors 154a and 154b.

In addition, a plurality of scanning signal lines 121 including a first control electrode 124a and a plurality of gate conductors including a second control electrode 124b are formed on the gate insulating layer 140.

In this case, the scanning signal line 121 transmits a scanning signal, and can mainly extend in a horizontal direction. The first control electrode 124a can extend upward from the scanning signal line 121. The second control electrode 124b is separated from the scanning signal line 121. Though not illustrated, the second control electrode 124b can include a storage electrode (not shown) that extends in a vertical direction. The first control electrode 124a can overlap part of the first semiconductor 154a , for example, the channel region thereof. The second control electrode 124b can overlap part of the second semiconductor 154b , for example, the channel region 152b thereof.

In addition, a first passivation layer 180a is formed on the gate insulating layer 140 and on the gate conductors. The first passivation layer 180a and the gate insulating layer 140 include a contact hole 183a exposing the source region of the first semiconductor 154a , a contact hole 185a exposing the drain region thereof, a contact hole 183b exposing the source region 153b of the second semiconductor 154b , and a contact hole 185b exposing the drain region 155b thereof. The first passivation layer 180a includes a contact hole 184 that exposes the second control electrode 124b.

Next, a plurality of data conductors including a plurality of data lines 171, a plurality of driving voltage lines 172, a plurality of first output electrodes 175a , and a plurality of second output electrodes 175b are formed on the first passivation layer 180a.

In this case, the data line 171 transmits a data signal, and mainly extends in the vertical direction to cross the scanning signal line 121. Each data line 171 includes a plurality of first input electrodes 173a that extend toward the first control electrode 124a.

In addition, the driving voltage line 172 transmits a driving voltage, and mainly extends in the vertical direction to cross the scanning signal line 121. Each driving voltage line 172 includes a plurality of second input electrodes 173b that extend toward the second control electrode 124b . When the second control electrode 124b includes the storage electrode, the driving voltage line 172 can include a portion that overlaps the storage electrode.

The first and second output electrodes 175a and 175b can have island-like shapes that are separated from each other, and are also separated from the data line 171 and the driving voltage line 172. The first input electrode 173a and the first output electrode 175a face each other on the first semiconductor 154a , and the second input electrode 173b and the second output electrode 175b face each other on the second semiconductor 154b.

In this case, the first input electrode 173a and the first output electrode 175a can be respectively connected to the source and drain regions of the first semiconductor 154a via the contact holes 183b and 185b . The first output electrode 175a can be connected to the second control electrode 124b via the contact hole 184. The second input electrode 173b and the second output electrode 175b can be respectively connected to the source and drain regions 153b and 155b of the second semiconductor 154b via the contact holes 183b and 185b.

The first control electrode 124a , the first input electrode 173a , and the first output electrode 175a form a switching thin film transistor Qs along with the first semiconductor 154a . The second control electrode 124b , the second input electrode 173b , and the second output electrode 175b form a driving thin film transistor Qd along with the second semiconductor 154b . Structures of the switching thin film transistor Qs and the driving thin film transistor Qd are not limited thereto, and they can be variously modified.

A second passivation layer 180b that can be formed of an inorganic insulating material such as a silicon nitride or a silicon oxide can be formed on the data conductors. The second passivation layer 180b can have a flat surface by removing steps in order to improve luminous efficiency of an organic light-emitting element (for example, organic light-emitting diode (OLED)) to be formed thereon. The second passivation layer 180b can have a second contact hole 185c that exposes the output electrode 175b.

A plurality of pixel electrodes 191 are formed on the second passivation layer 180b.

For example, the pixel electrode 191 of each pixel PX is physically and electrically coupled to the second output electrode 175b via the contact hole 185c of the second passivation layer 180b . The pixel electrode 191 can include a semi-transmissive conductive material or a transflective conductive material.

In addition, a pixel definition layer (referred to as a partition wall) 360 having a plurality of openings that exposes the pixel electrode 191 can be formed on the second passivation layer 180b . The openings of the pixel definition layer 360 exposing the pixel electrode 191 can define each pixel area. The pixel definition layer 360 can be omitted.

A light-emitting member 370 is formed on the pixel definition layer 360 and on the pixel electrode 191. The light-emitting member 370 can include a first organic common layer 371, a plurality of emission layers 373, and a second organic common layer 375 that are sequentially laminated.

For example, the first organic common layer 371 includes at least one of a hole injecting layer and a hole transport layer. The first organic common layer 371 can be formed across an entire surface of the display area in which the pixels PX are formed, or only in each pixel PX area.

In addition, the emission layers 373 can be respectively formed on the pixel electrodes 191 of the corresponding pixels PX. The emission layer 373 can be formed of an organic material which uniquely emits light of the primary colors such as red, green, and blue, and can have a structure in which a plurality of organic material layers emitting light of different colors are laminated.

In addition, the second organic common layer 375 can include, for example, at least one of an electron transport layer and an electron injecting layer that are sequentially laminated. The second organic common layer 375 can be formed across the entire surface of the display area in which the pixels PX are formed, or only in each pixel PX area.

In this case, the first and second organic common layers 371 and 375 are provided to improve luminous efficiency of the emission layer 373, and either one of the first and second organic common layers 371 and 375 can be omitted.

Next, a common electrode 270 transmitting a common voltage Vss is formed on the light-emitting member 370. The common electrode 270 can include a transparent conductive material. For example, the common electrode 270 is formed of a transparent conductive material, or is formed to have a light-transmitting property by thinly laminating a metal such as calcium (Ca), barium (Ba), magnesium (Mg), aluminum (Al), silver (Ag), etc.

The pixel electrode 191, the light-emitting member 370, and the common electrode 270 of each pixel PX form a light-emitting element LD, and one of the pixel electrode 191 and the common electrode 270 can be a cathode while the other can be an anode. In addition, the storage electrode and the driving voltage lines 172 overlapping each other can form a storage capacitor Cst.

The display element layer 200 according to the current exemplary embodiment can be a top emission type in which internal light from the light-emitting member 370 is emitted toward a front side of the first substrate 112 to display an image.

An encapsulation layer 379 can be further formed on the common electrode 270. The encapsulation layer 379 can prevent permeation of external moisture and/or oxygen by encapsulating the light-emitting member 370 and the common electrode 270. An upper surface of the encapsulation layer 379 can be flat. The encapsulation layer 379 can include a plurality of thin film layers. For example, the encapsulation layer 379 has a multi-layered structure that includes at least one of an inorganic layer and an organic layer.

As such, the display element layer 200 including the thin film transistor, the light-emitting element LD, and the encapsulation layer 379 can be completed.

If necessary, a polarization film (not shown) can be formed on the display element layer 200.

The polarization film changes an optical axis of light that passes through the display element layer 200 to be emitted to the outside. Generally, the polarization film has a structure in which a transparent protection film is laminated on one or both sides of the polarizer that is formed of a polyvinyl alcohol-based resin.

More specifically, the polarization film can have a structure in which a protection film such as a triacetyl cellulose (TAC) film or the like is adhered to a polarizer having a structure in which polyvinyl alcohol (hereinafter referred to as PVA)-based molecule chains are aligned in a predetermined direction and in which an iodine-based compound or a dichroic polarizing material is included. In addition, the polarizer and the protection film can be generally adhered together by an aqueous adhesive that is formed of a polyvinyl alcohol-based solution. In the present disclosure, the polarization film is not limited thereto, and the polarization film can have various structures and can be formed of various materials.

Next, the display device according to the current exemplary embodiment includes the second substrate 120 that is separated from the first substrate 112 including the display area DA.

In the present disclosure, the second substrate 120 includes the second pad region PA2. The driving unit 380 serves to connect a flexible printed circuit substrate 500, which is formed with a control circuit for transmitting a control signal to the display area DA, to the display area DA.

In addition, the driving unit 380 includes a driver integrated circuit (IC) that is mounted as a chip, and is formed in the second pad region PA2 of the second substrate 120.

In the display device according to the current exemplary embodiment, the driving unit 380 can be mounted on the second pad region PA2 of the second substrate 120 in the form of chip-on-glass or chip-on-plastic. Accordingly, in the current exemplary embodiment, the second substrate 120 can be a glass substrate or a substrate including plastic such as polyethylene terephthalate (PET), polyethylene naphthalate (PEN), polycarbonate (PC), polyarylate (PAR), polyetherimide (PEL), polyether sulfone (PES), or polyimide (PI).

In this case, as shown in FIGS. 1 and 3, the connecting portion 400 can be connected to a first side end portion of the second pad region PA2, and the flexible printed circuit board 500 can be connected to a second side end portion thereof, which is opposite relative to the first side end portion.

The flexible printed circuit board 500 is provided with various circuit elements for transmitting driving and control signals to the display area DA. These circuit elements can be electrically connected to signal lines 450 of the display area DA, which are included in the first substrate 112 via a wiring part 410 included in the wires (not shown) and the connecting portion 400 of the flexible printed circuit board 500. The driving and control signals of the flexible printed circuit board 500 are transmitted to the first substrate via the connecting portion 400, thereby allowing an image to be displayed in the display area DA.

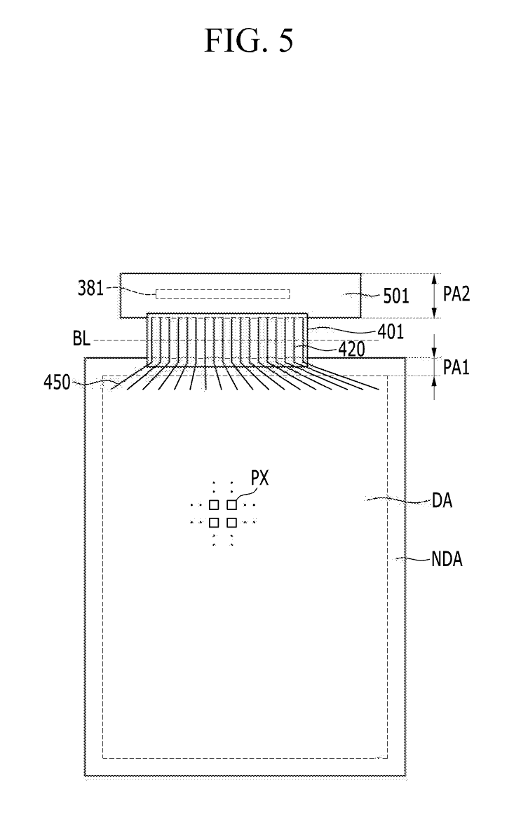

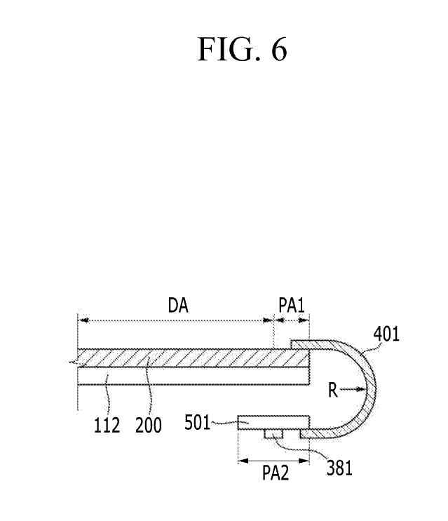

FIG. 5 is a top plan view of a display device according to another exemplary embodiment. FIG. 6 is a cross-sectional view of the display device of FIG. 5 folded back along a bending line.

Referring to FIGS. 5 and 6, in the current exemplary embodiment, the second substrate 120 is a flexible printed circuit board 501. In this case, a driving unit 381 is formed directly on the flexible printed circuit substrate 501, and can be electrically coupled to a display area DA of the first substrate 112 via a connecting portion 401 that is connected to one end portion of the flexible printed circuit substrate 501. Accordingly, in one exemplary embodiment, a region on the flexible printed circuit board 501 where the driving unit 381 is positioned can be called a second pad region PA2.

Referring back to FIGS. 1 and 3, the connecting portion 400 is adhered to the first pad region PA1 of the first substrate 112 and the second pad region PA2 of the second substrate 120, serving to electrically couple the signal lines 450 of the first substrate 112 to the driving unit 380 of the second substrate 120.

In this case, the connecting portion 400 can be formed of a material that is extended at an extension rate of in the range of about 2% and about 100%. In this case, the extension rate is a ratio of a length of the connecting portion after the extension to a length thereof before the extension. The connecting portion 400 can be formed of, for example, copper (Cu), aluminum (Al), at least one alloy of these metals, or one or more selected from a group of silver (Ag), graphene, and a graphene oxide, but it is not limited thereto.

In addition, in the display device of the present disclosure, the connecting portion 400 includes a portion in which a bending line BL along which the display device is folded or bent is located. Accordingly, as shown in FIG. 2, based on the bending line BL of the connecting portion 400, the second substrate 120 can be folded or bent to overlap the first substrate 112 at an opposite side of the display area DA.

For example, when the first pad region PA1 and the second pad region PA2 are connected by the connecting portion 400 that is formed of the material having the extension rate in the range of about 2% and about 100%, little stress is applied to the first substrate 112 where the display element layer 200 is formed even if the display device is folded or bent along the bending line BL, thereby easily preventing cracks and the like from being generated and causing damage to the display element layer 200. Further, in the display device of the present disclosure, a bending portion having a very small curvature radius, which is difficult in typical flexible displays, can be realized. That is, when the display device of the present disclosure including the connecting portion 400 as described above is folded or bent, a curvature radius R of the connecting portion 400 can be easily set to be about 1.5R or less, or about 1R or less.

In addition, as in the present disclosure, when the second pad region PA2 formed with the driving unit 380 is physically separated from the first substrate 112 including the display area DA and the connecting portion 400 is then used to connect them, a width of the first pad region PA1 can easily be set to about 1.5 mm or less. Accordingly, in the display device of the present disclosure, respective widths of the peripheral area NDA including the first pad region PA1 can be manufactured to be less than about 1.5 mm. Accordingly, a dead space can dramatically decrease in the display device, thereby realizing the display device having virtually no bezel.

At least one of the first and second pad regions PA1 and PA2 and the connecting portion 400 can be connected by a thermosetting adhesive. In the present disclosure, since the thermosetting adhesive adds adhesiveness when heated, an adhesive composition is coated and predetermined heat is then applied to connect one side of the first pad region PA1 and/or the second pad region PA2 to the connecting portion 400, or a film-type adhesive is attached and predetermined heat is then applied to connect one side of the first pad region PA1 and/or the second pad region PA2 to the connecting portion 400.

The connecting portion 400 includes the wiring part 410 that electrically couples the signal lines 450 of the first substrate 112 to the driving unit 380.

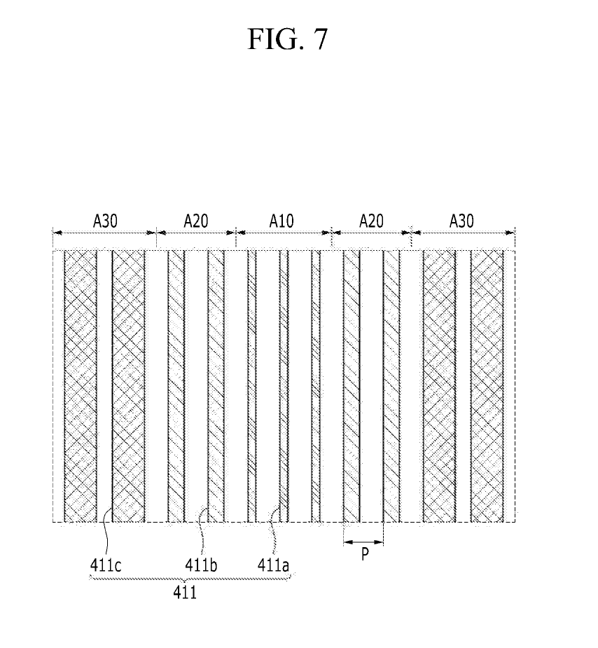

FIG. 7 shows a partial enlarged view of one illustrative wiring part 411 included in the display device of the present disclosure.

In the present disclosure, the connecting portion 400 can include a first region A10 that includes a first wiring part 411a , a second region A20 that neighbors the first region A10 and includes the second wiring part 411b , and a third region A30 that neighbors the second region A20 and includes a third wiring part 411c.

Here, the first wiring part 411a , the second wiring part 411b , and the third wiring part 411c are formed in the shape of a straight line, and can be arranged to be substantially parallel in the same direction.

In this case, widths of each wiring part 410 formed in the first region A10, the second region A20, and the third region A30 can be adjusted to have different resistances. That is, the width of the first wiring part 411a can be formed to be less than that of the second wiring part 411b , and the width of the second wiring part 411b can be formed to be less than that of the third wiring part 411c . Accordingly, the first wiring part 411a , the second wiring part 411b , and the third wiring part 411c , which are respectively formed in the first region A10, the second region A20, and the third region A30, have different resistances.

For example, the second wiring part 411b has a higher resistance than the first wiring part 411a since it has the same length as the first wiring part 411a but a greater width, and the third wiring part 411c has a higher resistance than the second wiring part since it has the same length as the second wiring part 411b but a greater width. As a result, the resistance of the first wiring part 411a can be greater than that of the second wiring part 411b , and the resistance of the second wiring part 411b can be greater than that of the third wiring part 411c . This is to compensate differences in resistance which are caused as lengths of the signal lines 450 of the first substrate 112 connected to the wiring part 410 of the connecting portion 400 increase closer to edges of the first substrate 112 from a center thereof.

In this case, pitches between the respective wiring parts in each region of the connecting portion 400 can be adjusted together.

For example, when the width of the connecting portion 400 corresponds to about 80% of the width of the first substrate 112, a pitch of the first wiring part 411a formed in the first region A10 can be about 40 μm or more. In addition, a pitch of the second wiring part 411b formed in the second region A20 can be about 44 μm or more, and a pitch of the third wiring part 411c formed in the third region A30 can be about 48 μm or more. In this case, as shown in FIG. 7, the pitch P can mean the distance from an edge line of one wiring part to an edge line of the neighboring wiring part.

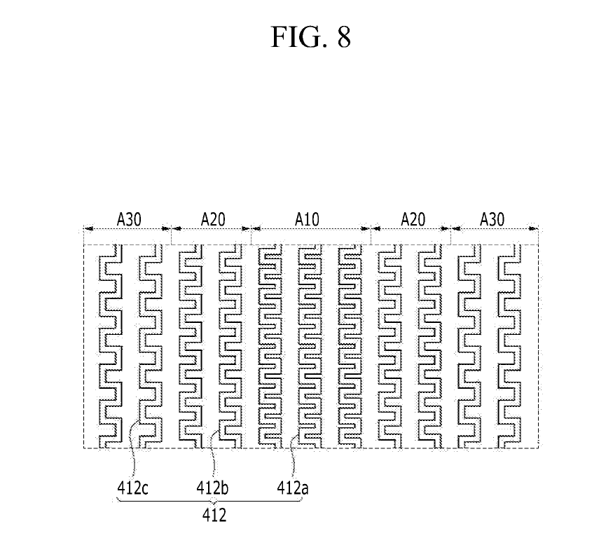

FIG. 8 shows a partial enlarged view of another illustrative wiring part 412 included in the display device of the present disclosure.

In the present disclosure, a wiring part 412 included in the connecting portion 400 has, as shown in FIG. 8, lengths that are different from each other.

In this case, a first wiring part 412a , a second wiring part 412b , and a third wiring part 412c are formed in the shape of protrusions and depressions where a convex portion and a recess portion are alternately repeated, and can be arranged to be substantially parallel in the same direction.

In addition, the first wiring part 412a can include the largest number of protrusion and depression patterns, the second wiring part 412b can include a smaller number of protrusion and depression patterns than the first wiring part 412a , and the third wiring part 412c can include a smaller number of protrusion and depression patterns than the second wiring part 412b . Accordingly, in the current exemplary embodiment, the connecting portion 400 includes the wiring part 412 having a shape in which the first wiring part 412a is formed longer than the second wiring part 412b and the second wiring part 412b is formed longer than the third wiring part 412c.

For example, the second wiring part 412b has higher resistance than the first wiring part 412a since it has the same width as the first wiring part but a longer length, and the third wiring part 412c has higher resistance than the second wiring part since it has the same width as the second wiring part 412b but a longer length. As a result, the resistance of the first wiring part 412a can be greater than that of the second wiring part 412b , and the resistance of the second wiring part 412b can be greater than that of the third wiring part 412

In this case, as described above, differences in resistance, which are caused as lengths of the signal lines 450 of the first substrate 112 connected to the wiring part 412 of the connecting portion 400 increase closer to edges of the first substrate 112 from a center thereof, can be compensated.

In the present disclosure, the wiring part 410 included in the connecting portion 400 is not limited to the aforementioned examples, and can be formed such that the widths of the wiring part 410 gradually increase closer to the edges of the connecting portion 400 from the center thereof.

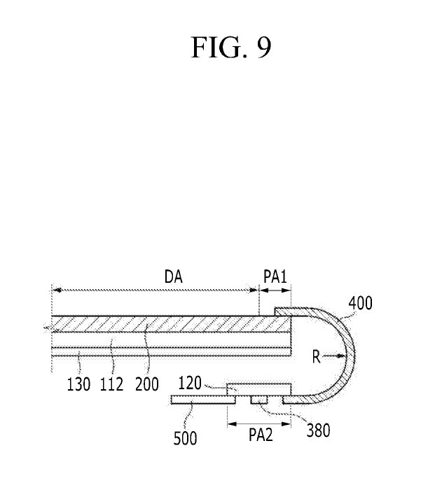

Next, the display device according to one exemplary embodiment can further include, as shown in FIG. 9, a lower protection film 130 that is attached under the first substrate 112 to protect it.

In this case, the lower protection film 130 can include any one material selected from polyethylene terephthalate (PET), polyethylene naphthalate (PEN), polyethylene sulfide (PES), and polyethylene (PE), and it is not particularly limited thereto. That is, the lower film can be formed of a polymer material having high elasticity.

In addition, a thickness of the lower protection film 130 can be about 10 μm to about 200 μm. This is because the lower protection film 130 having a thickness of less than 10 μm is too thin to protect a lower part of the display device, and the lower protection film 130 having a thickness of greater than 200 μm cannot allow the display device to have flexibility when it is attached under the first substrate 112.

While the inventive technology has been described in connection with what is presently considered to be practical exemplary embodiments, it is to be understood that the invention is not limited to the disclosed embodiments, but, on the contrary, it is intended to cover various modifications and equivalent arrangements included within the spirit and scope of the appended claims.

What is claimed is:

1. A display device, comprising:
a first substrate including a display area configured to display an image and a first pad region neighboring the display area;
a second substrate including a second pad region, wherein the second pad region includes a driving circuit; and
a connector connecting the first pad region to the second pad region, wherein the connector includes a wiring that electrically connects the display area to the driving circuit.

2. The display device of claim 1, wherein the connector includes:
a first region including a first wiring;
a second region adjacent to the first region and including a second wiring; and
a third region adjacent to the second region and including a third wiring.

3. The display device of claim 2, wherein the width of the first wiring is less than the width of the second wiring, and wherein the width of the second wiring is less than the width of the third wiring.

4. The display device of claim 2, wherein the length of the first wiring is greater than the length of the second wiring, and wherein the length of the second wiring is greater than the length of the third wiring.

5. The display device of claim 2, wherein each of the first to third wirings has a square wave shape.

6. The display device of claim 5, wherein each of the first to third wirings has a plurality of bent portions, wherein a first distance between of adjacent bent portions of the third wiring is greater than a second distance between adjacent bent portions of the second wiring, and wherein the second distance is greater than a third distance between adjacent bent portions of the first wiring.

7. The display device of claim 1, wherein the second substrate includes a printed circuit board (PCB).

8. The display device of claim 1, wherein the second pad region has a first end connected to the connector and a second end opposing the first end, and wherein the second pad region further includes a PCB electrically connected to the second end.

9. The display device of claim 1, wherein the connector is formed of a material having an extension rate in the range of about 2% to about 100%.

10. The display device of claim 1, wherein the connector is formed of one or more of copper (Cu), aluminum (Al), at least one alloy of those metals, silver (Ag), graphene, and a graphene oxide.

11. The display device of claim 1, wherein at least one of the first and second pad regions is connected to the connector via a thermosetting adhesive.

12. The display device of claim 1, wherein the connector is bent toward an opposite side of the display area of the first substrate, and wherein the second substrate overlaps the first substrate in the depth dimension of the display device.

13. The display device of claim 12, wherein a curvature radius of the connector is about 1.5R or less.

14. The display device of claim 1, further comprising a protection film formed on the first substrate and configured to protect the first substrate.

15. The display device of claim 1, wherein the second substrate includes a flexible PCB.

16. A display device, comprising:
a first substrate including a display area and a first pad region adjacent to the display area;
a second substrate including a second pad region, wherein the second pad region includes a driving circuit; and
a connector connecting the first pad region to the second pad region, wherein the width of the second pad region is greater than the width of the first pad region.

17. The display device of claim 16, wherein the connector includes a wiring configured to electrically connect the display area to the driving circuit.

18. The display device of claim 17, further comprising a display element layer formed on the first substrate and configured to display an image, wherein the connector has first and second ends opposing each other, wherein the first end of the connector is formed on the display element layer, and wherein the second end of the connector is formed on the second substrate.

19. The display device of claim 16, further comprising a flexible PCB formed on the second substrate, wherein the flexible PCB and the second end of the connector are formed on the same side of the second substrate.

20. The display device of claim 17, wherein the wiring includes a plurality of wirings including a leftmost wiring and a rightmost wiring, and wherein the widths of the wirings decrease as a function of distance from the leftmost and rightmost wirings.
